(19) United States
(12) Patent Application Publication
(10) Pub. No.: US 2023/0039939 A1
(43) Pub. Date: Feb. 9, 2023

(54) LIFT PIN, WAFER PROCESSING APPARATUS COMPRISING SAME, AND METHOD FOR PRODUCING WAFERS

(71) Applicant: SK Siltron Co., LTD., Gyeongsangbuk-do (KR)

(72) Inventors: Mi Ri KIM, Gyeongsangbuk-do (KR); Yong Jin KIM, Gyeongsangbuk-do (KR); Dong Ho KANG, Gyeongsangbuk-do (KR)

(21) Appl. No.: 17/790,791

(22) PCT Filed: Jan. 3, 2020
(86) PCT No.: PCT/KR2020/000084

§ 371 Date: Jul. 29, 2022

(30) Foreign Application Priority Data
Jan. 2, 2020 (KR) 10-2020-0000057

(51) Int. Cl. H01L 21/687; H01L 21/02

(52) U.S. Cl. CPC H01L 21/68742; H01L 21/02532; H01L 21/02634; H01L 21/02381; H01L 21/02661

(57) ABSTRACT

One embodiment provides a lift pin comprising: a body which is inserted into a through-hole in a susceptor; and a head provided at the end of the body to come into contact with the underside of a wafer, wherein the top surface of the head is formed to have a concavoconvex structure.

### TECHNICAL FIELD

Embodiments relate to a wafer processing apparatus which performs various processes, such as deposition, etching, heat treatment, etc., and more particularly, to a lift pin which supports a wafer to place the wafer on a susceptor, a wafer processing apparatus including the same, and a method for producing a wafer.

### BACKGROUND ART

Wafers, such as a single crystal silicon wafer, undergo various processing operations, such as deposition of a designated material layer on the surface of a wafer, etching of the designated material layer on the surface of the wafer, heat treatment of the entire wafer, etc. These processing operations may be divided into a batch-type processing method in which a plurality of wafers is simultaneously received in a reactor, i.e., a chamber, so as to be processed, and a single-type processing method in which only one wafer is processed at a time.

Thereamong, in the single-type processing method, a wafer is placed on the susceptor or a chuck, and is then processed, and a wafer processing apparatus having a structure, in which the rear surface of the wafer is lifted by lift pins via through holes formed at designated positions of the susceptor when the wafer is placed on the susceptor or the wafer is separated from the susceptor after processing, is known.

In order to vapor-grow a designated material layer on the wafer using such a processing apparatus, after the wafer has been loaded into a chamber while being supported by the lift pins, the designated material layer may be vapor-grown on the wafer.

However, the conventional lift pins and the wafer processing apparatus including the same have the following problems.

A kind of contamination or defect referred to as pin marks may occur on parts of the rear surface of the wafer, which are lifted by the lift pins. It is assumed that the reason why the pin marks occur is that temperature uniformity of the wafer is reduced due to local heat loss caused by the lift pins, considering that pin marks mainly occur during a process accompanied by heat having a high temperature (i.e., epitaxial growth, heat treatment, etc.).

In order to reduce occurrence of the pin marks, a method for manufacturing lift pins using a material having low thermal conductivity, such as SiC, quartz or the like, instead of graphite which was conventionally used to manufacture lift pins, or a method for rounding the upper surface of the head of a lift pin coming into contact with the rear surface of a wafer has been proposed.

However, in the case that the lift pins which are consumables are formed of an expensive material, such as SiC, instead of graphite, the manufacturing costs of the lift pins are increased, and occurrence of pin marks is still not effectively reduced in spite of such material change or shape enhancement.

### DISCLOSURE

### Technical Problem

Embodiments provide a lift pin which may reduce or remove a pin mark formed on the surface of a wafer, a wafer processing apparatus including the same, and a method for producing a wafer.

### Technical Solution

One embodiment provides a lift pin including a body inserted into a through hole formed in a susceptor; and a head provided at one end of the body to come into contact with a rear surface of a wafer, wherein an upper surface of the head is formed to have a concavo-convex structure.

The upper surface of the head may form a curved surface configured to be convex towards the rear surface of the wafer.

The curved surface may have a radius of curvature of 8 to 15 mm.

The respective convex parts of the concavo-convex structure may have a height of 0.5 to 1.5 μm.

Among respective convex parts of the concavo-convex structure, a density of the convex parts in a central region of the head may be greater than a density of the convex parts in an edge region of the head.

Among respective convex parts of the concavo-convex structure, a height of the convex parts in a central region of the head may be greater than a height of the convex parts in an edge region of the head.

The body and the head may be formed of glassy carbon.

The upper surface of the head may include a first layer formed to have a flat surface, and a second layer selectively disposed on the first layer, the first layer may be exposed between regions of the second layer, exposed parts of the first layer may form concave parts, and the second layer may form convex parts.

At least one of shapes of the exposed parts of the first layer or a shape of the second layer configured to form the convex parts may be irregular.

Another embodiment provides a wafer processing apparatus including a disc-shaped susceptor provided with at least three through holes formed therethrough, and configured such that a wafer is placed thereon; at least three lift pins raised and lowered in a vertical direction to support the rear surface of the wafer, and provided to correspond to the through holes, respectively; and an elevation member configured to raise and lower the lift pins.

Yet another embodiment provides a method for producing a wafer, the method including (a) disposing a wafer processing apparatus comprising a disc-shaped susceptor provided with at least three through holes formed therethrough and configured such that the wafer is placed thereon, at least three lift pins, each lift pin comprising a body inserted into a corresponding one of the through holes in the susceptor and a head provided at one end of the body so as to come into contact with a rear surface of the wafer, raised and lowered in a vertical direction to support the rear surface of the wafer, and provided to correspond to the through holes, respectively, and an elevation member configured to raise and lower the lift pins, in a chamber; (b) disposing the wafer on surfaces of the lift pins, and raising the lift pins by the elevation member; (c) depositing an epitaxial layer on a surface of the wafer; and (d) removing a silicon layer deposited on the heads of the lift pins by supplying hydrogen gas to an upper region inside the chamber and supplying hydrogen gas and hydrogen chloride to a lower region inside the chamber.

Hydrogen gas may be supplied to the upper region and the lower region inside the chamber in operation (c).

The same amount of hydrogen gas may be supplied to the upper region and the lower region inside the chamber in operation (d).

### Advantageous Effects

In a lift pin and a wafer processing apparatus including the same according to one embodiment, a silicon layer is firmly fixed to the upper surface of a head of the lift pin due to the concavo-convex structure on the upper surface of the head, compared to the conventional lift pin, and thus, the silicon layer may maintain the state of being adhered to the upper surface of the head of the lift pin when a wafer is separated from the lift pin, and a pin mark may not occur on the rear surface of the wafer.

Further, in a method for processing a wafer according to another embodiment, after an epitaxial layer has been deposited on the surface of the wafer, the silicon layer deposited on the head of the lift pin may be removed by supplying hydrogen gas and hydrogen chloride to a lower region inside a chamber.

### DESCRIPTION OF DRAWINGS

FIG. 1 is a view showing a wafer processing apparatus according to one embodiment,

FIG. 2 is a view showing the action of a lift pin of FIG. 1,

FIGS. 3a to 3c are views illustrating problems of a conventional lift pin,

FIGS. 4a to 5 are views showing embodiments of the lift pin of FIG. 1,

FIG. 6 is a view illustrating the action of the lift pin according to one embodiment, and

FIG. 7 is a flowchart representing a method for producing a wafer according to one embodiment.

### BEST MODE

Hereinafter, embodiments will be described in more detail so as to concretely describe the present invention, with reference to the accompanying drawings.

However, the present invention may be variously modified and be implemented in various forms, and it will be understood that the scope of the present invention should not be interpreted as being limited to the embodiments set forth herein. The embodiments of the present invention are provided to make the description of the present invention thorough and to fully convey the scope of the present invention to those skilled in the art.

Further, relative terms, such as “first,” “second,” “above,” “below,” and the like when used herein do not necessarily require or imply any physical or logical relationship between substances or elements indicated by the terms or a sequence or order thereof, and may be only used to distinguish one substance or element from another substance or element.

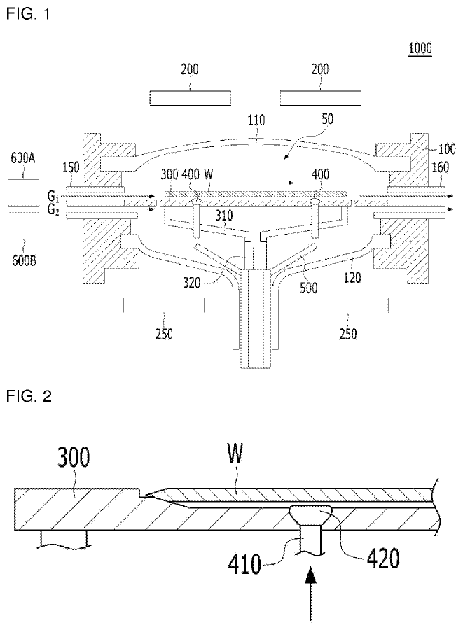

FIG. 1 is a view showing a wafer processing apparatus according to one embodiment. A wafer processing apparatus 1000 according to this embodiment is an apparatus which grows an epitaxial layer on a wafer, for example, a single-type wafer processing apparatus.

In more detail, the wafer processing apparatus 1000 has a chamber 50 surrounded by an upper dome 110, a lower dome 120 and dome attachments 100. The chamber 50 is a space in which a process of forming an epitaxial layer on a wafer W is performed. A gas inlet 150 and a gas outlet 160 configured to supply and discharge reaction gases therethrough are formed on one side surface and the other side surface opposite to the side surface of the chamber 50. Here, the gas inlet 150 may have two passages so as to supply first gas G1 and second gas G2 supplied from a first gas supply module 600A and a second gas supply module 600B to an upper region and a lower region inside the chamber 50, respectively.

The first gas supply module 600A and the second gas supply module 600B may be disposed adjacent to the gas inlet 150. The first gas supply module 600A may supply hydrogen gas to the upper region inside the chamber 50, and the second gas supply module 600B may supply hydrogen gas and hydrogen chloride to the lower region inside the chamber 50.

In more detail, the wafer processing apparatus 1000 has the chamber 50 surrounded by the upper dome 110, the lower dome 120 and the dome attachments 100. The chamber 50 is a space in which a process of forming an epitaxial layer on the wafer W is performed. The gas inlet 150 and the gas outlet 160 configured to supply and discharge reaction gases therethrough are formed on one side surface and the other side surface opposite to the side surface of the chamber 50.

A disc-shaped susceptor 300 on which the wafer W is placed is disposed in the chamber 50. The outer circumferential part of the lower surface of the susceptor 300 is supported by a susceptor support shaft 310 connected to a susceptor rotator 320, and the susceptor 300 is rotated together with the susceptor support shaft 310.

At least three through holes configured to allow lift pins 400 for raising and lowering the wafer W to pass therethrough are formed through the susceptor 300, and the lift pins 400 inserted into the through holes may support the wafer W.

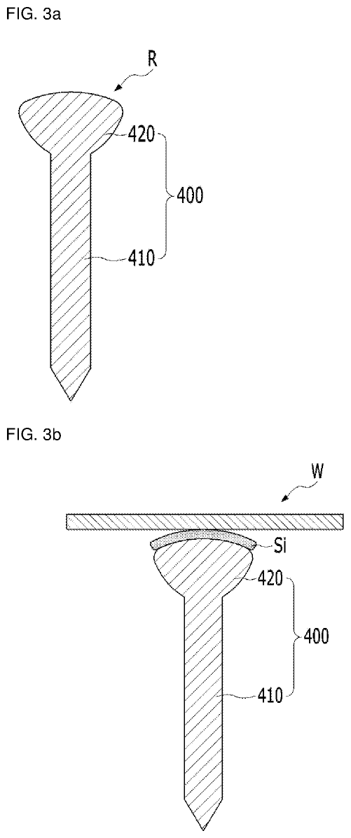

FIG. 2 is a view showing the action of the lift pin of FIG. 1. As shown in FIG. 2, the lift pin 400 includes a head 420 configured to come into contact with the wafer W and a body 410 inserted into the through hole in the susceptor 300 so as to pass therethrough. The wafer W disposed in the chamber 50 is moved upwards from the susceptor 300 by the lift pins 400 inserted into the through holes in the susceptor 300, and the heads 420 of the lift pins 400 come into contact with the rear surface of the wafer W and thus support the wafer W, as shown in this figure. Here, upward movement of the lift pins 400 is carried out through upward movement of an elevation member 500 configured to support the lift pins 400.

The wafer W may be disposed on the susceptor 300 by moving the susceptor 300 to the position of the wafer W by raising the susceptor support shaft 310 supporting the susceptor 300, as shown in FIG. 1. Here, the heads 420 of the lift pins 400 are received in the through holes in the susceptor 300. Referring to FIGS. 1 and 2, the lift pins 400 and the rear surface of the wafer W may be spaced apart from each other during a process of depositing the epitaxial layer on the wafer W, but the rear surface of the wafer W may come into contact with the lift pins 400 when the wafer W is raised.

As described above, a silicon wafer may be manufactured by growing an epitaxial layer to a designated thickness on the wafer W placed on the susceptor 300 by heating the wafer W to a high temperature by a plurality of first and second lamps 200 and 250 disposed above and below the susceptor 300 and supplying reaction gases to the inside of the chamber 50.

After growth of the epitaxial layer, the susceptor 300 may be lowered by lowering the susceptor support shaft 310. Thereafter, a transport blade (not shown) is introduced into the chamber 50, the wafer W is placed on the transport blade by lowering the lift pins 400, and thereby, the wafer W may be moved from the lift pins 400 to the transport blade. Subsequently, the wafer W together with the transport blade may be moved from the wafer processing apparatus 1000 to the outside.

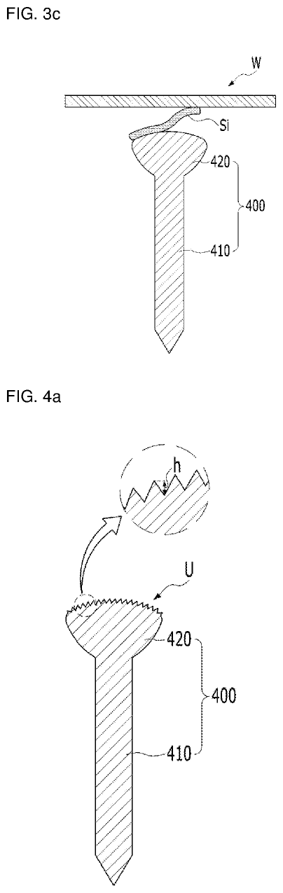

FIGS. 3a to 3c are views illustrating problems of a conventional lift pin.

FIG. 3a shows the conventional lift pin 400, the lift pin 400 includes a body 410 and a head 420, and the body 410 and the head 420 are formed of the same material, for example, the body 410 and the head 420 may be formed of glassy carbon, graphite, quartz or silicon carbide (SiC). The upper surface of the head 420 may form a curved surface having a designated curvature.

Referring to FIG. 3b, after the above-described process of depositing an epitaxial layer while supporting the wafer W by the lift pin 400, a silicon (Si) layer from reaction gases is deposited on the upper surface of the head 420 of the lift pin 400.

Here, as shown in FIG. 3c, when wafer W is separated from the lift pin 400, a portion of the silicon (Si) layer is adhered to the rear surface of the wafer W, and is thus released from the upper surface of the head 420 of the lift pin 400.

The silicon (Si) layer adhered to the rear surface of the wafer W may be a kind of contamination or defect referred to as a pin mark.

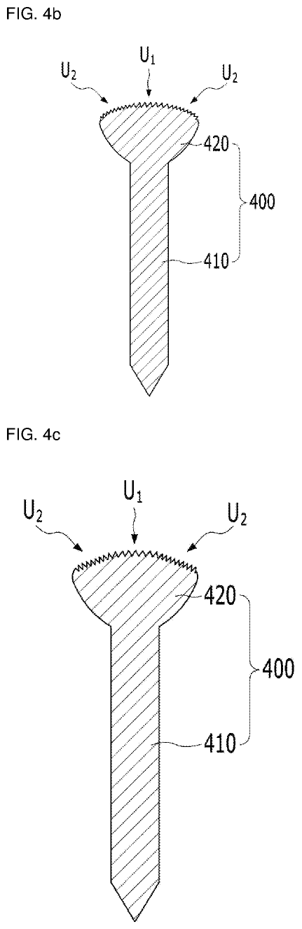

FIGS. 4a to 4c and FIG. 5 are views showing embodiments of the lift pin of FIG. 1.

As shown in FIG. 4a, a lift pin 400 according to one embodiment may include a body 410 inserted into the through hole in the susceptor, and a head 420 provided at one end of the body 410 so as to come into contact with the rear surface of the wafer, and the upper surface of the head 420 is formed to have a concavo-convex structure U.

Further, the upper surface of the head 420 may form a curved surface which is convex upwards, i.e., towards the rear surface of the wafer, and such an upper surface of the head 420 serves to reduce an area thereof contacting the rear surface of the wafer.

The radius of curvature of the curved upper surface of the head 420 may be 8 to 15 mm. When the radius of curvature of the upper surface of the head 420 is less than 8 mm, the upper surface of the head 420 is excessively convex and may thus have difficulty in stably supporting the wafer, and, when the radius of curvature of the upper surface of the head 420 is greater than 15 mm, a contact area between the rear surface of the wafer and the upper surface of the head 420 may be excessively large.

Here, concave and convex parts are formed on the upper surface of the head 420, and thus, the radius of curvature of the upper surface of the head 420 may be the radius of the curvature of a part of the head 420 other than the concavo-convex structure. Such a concavo-convex structure may be formed by mechanically processing or chemical etching the upper surface of the head 420 during a process for manufacturing the lift pin 400.

The concavo-convex structure includes concave parts and convex parts and, in the embodiment of FIG. 4a, the height h of the convex parts may be 0.5 to 1.5 micrometers. Here, the height h of the convex parts may be the shortest distance from the bottom surfaces of the concave parts to the highest points of the convex parts, the shapes or the heights of the convex parts may not be uniform, and thus, the height h of the convex parts may be the mean height of the convex parts.

When the height h of the convex parts is greater than 1.5 micrometers, the upper surface of the head 420 coming into direct contact with the rear surface of the wafer may be excessively irregular, and, when the height h of the convex parts is less than 0.5 micrometers, adhesion of the head 420 to the silicon (Si) layer may be decreased.

In an embodiment shown in FIG. 4b, the height h1 of concave and convex parts U1 in the central region of the upper surface of the head 420 may be greater than the height h2 of concave and convex parts U2 in the edge region of the upper surface of the head 420. That is, since the central region of the upper surface of the head 420 comes into direct contact with the rear surface of the wafer, the height h1 of the concave and convex parts U1 may be relatively great, and the height h2 of the concave and convex parts U2 in the edge region of the upper surface of the head 420 may be relatively small.

In the case in which the edge region of the upper surface of the head 420 does not come into direct contact with the rear surface of the wafer, the concavo-convex structure may not be formed on the edge region of the upper surface of the head 420, but, since the above-described concavo-convex structure is formed during the process of manufacturing the lift pin 400, it may be advantageous in terms of the manufacturing process to allow the concave and convex parts U2 in the edge region of the upper surface of the head 420 to have a relatively small height h2, as described above, or to vary the density of concave and convex parts, as described below, rather than not to form a concavo-convex structure in the edge region of the upper surface of the head 420.

In an embodiment shown in FIG. 4c, the density of concave and convex parts U1 in the central region of the upper surface of the head 420 may be greater than the density of concave and convex parts U2 in the edge region of the upper surface of the head 420. That is, since the central region of the upper surface of the head 420 comes into direct contact with the rear surface of the wafer, the density of the concave and convex parts U1 may be relatively high, and the density of the concave and convex parts U2 in the edge region of the upper surface of the head 420 may be relatively low.

In an embodiment shown in FIG. 5, the upper surface of the head 420 may include a first layer disposed in the direction of the body 410, and a second layer disposed on the first layer. The first layer may have a regular thickness and a flat upper surface, and the first layer may have a concavo-convex structure. However, the first and second layers may not be physically distinguished.

In more detail, the first layer may be exposed between regions of the second layer, exposed parts of the first layer may form concave parts, and the second layer may form convex parts, thereby being capable of forming the concavo-convex structure.

In FIG. 5, the shapes of the exposed parts of the first layer, i.e., the areas and/or the patterns of the concave parts, may be irregular, and the shapes of the second layer, i.e., the areas, the patterns and/or the heights of the convex parts, may be irregular.

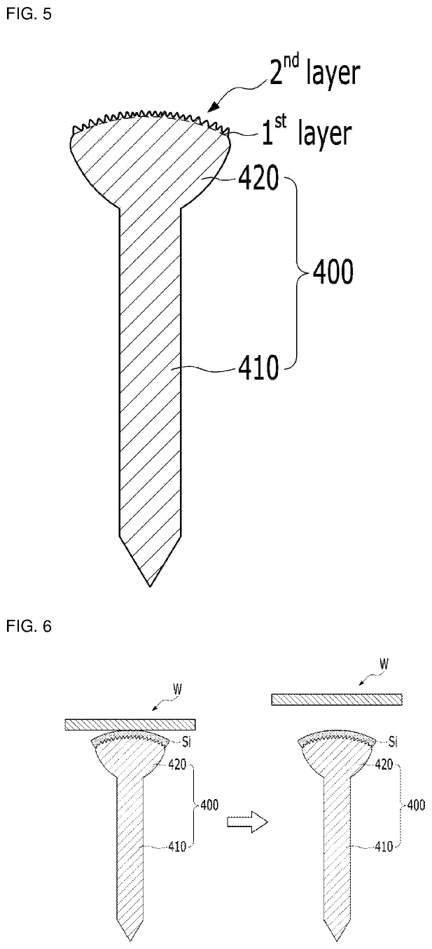

FIG. 6 is a view illustrating the action of the lift pin according to one embodiment.

When the above-described process of depositing an epitaxial layer has been completed while supporting the wafer W by the lift pin 400, a silicon (Si) layer from reaction gases is deposited on the upper surface of the head 420 of the lift pin 400.

At this time, the silicon (Si) layer is firmly fixed to the upper surface of the head 420 of the lift pin 400 due to the concavo-convex structure of the upper surface of the head 420 compared to the conventional lift pin, and thus, the silicon (Si) layer may maintain the state of being adhered to the upper surface of the head 420 of the lift pin 400 when the wafer W is separated from the lift pin 400. Therefore, a pin mark may not be formed on the rear surface of the wafer W.

The lift pins shown in FIGS. 4a to 5 may be used in the wafer processing apparatus of FIG. 1, thereby being capable of improving the quality of the wafer after formation of the epitaxial layer thereon, and particularly being capable of preventing occurrence of a pin mark on the rear surface of the wafer W.

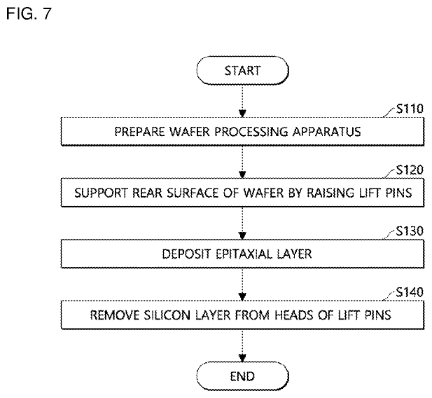

FIG. 7 is a flowchart representing a method for producing a wafer according to one embodiment.

First, the wafer processing apparatus of FIG. 1 is prepared (S110). In more detail, the wafer processing apparatus including a susceptor formed to have a disc shape and provided with at least three through holes formed therethrough, at least three lift pins, each of which includes a body inserted into a corresponding one of the through holes in the susceptor and a head provided at one end of the body so as to come into contact with the rear surface of a wafer, and, which are raised and lowered in the vertical direction to support the rear surface of the wafer and are provided to correspond to the through holes, and an elevation member configured to raise and lower the lift pins, in a chamber is prepared.

Thereafter, the wafer is disposed on the surface of the susceptor, and the lift pins are raised by the elevation member so as to support the rear surface of the wafer (S120).

Thereafter, an epitaxial layer is deposited on the surface of the wafer (S130).

Thereafter, a silicon layer deposited on the heads of the lift pins may be removed by supplying hydrogen gas to the upper region inside the chamber and supplying hydrogen gas and hydrogen chloride (HCl) to the lower region inside the chamber (S140).

Here, in the deposition of the epitaxial layer on the surface of the wafer, hydrogen gas may be supplied to the upper region and the lower region inside the chamber. In more detail, both the first gas and the second gas supplied from the first gas supply module and the second gas supply module may include hydrogen gas.

Further, in removal of the silicon layer deposited on the heads of the lift pins, the same amount of hydrogen gas may be supplied to the upper region and the lower region inside the chamber, and hydrogen chloride (HCl) gas may be further supplied to the lower region.

The silicon layer deposited on the heads of the lift pins may be removed due to the action of the above-described hydrogen chloride gas, and, although some parts of the silicon layer remain on the heads of the lift pins, the remaining parts of the silicon layer are adhered to the concavo-convex structure on the upper surfaces of the heads of the lift pins and are thus not transferred to the rear surface of the wafer during a process of separating the wafer from the lift pins.

Although the embodiments of the present invention have been described in detail with reference to illustrative embodiments and drawings thereof, the present invention as described above is not limited to these embodiments, and it should be apparent to those skilled in the art that various substitutions, changes and modifications which are not exemplified herein but are still within the spirit and scope of the present invention may be made.

Therefore, the scope of the present invention is defined not by the detailed description, but by the claims and their equivalents, and all variations within the scope of the claims and their equivalents are to be construed as being included in the present invention.

### INDUSTRIAL APPLICABILITY

A lift pin, a wafer processing apparatus including the same, and a method for producing a wafer according to embodiments may be used to grow an epitaxial layer on a silicon wafer.

1. A lift pin comprising:
a body inserted into a through hole formed in a susceptor; and
a head provided at one end of the body to come into contact with a rear surface of a wafer,
wherein an upper surface of the head is formed to have a concavo-convex structure.

2. The lift pin according to claim 1, wherein the upper surface of the head forms a curved surface configured to be convex towards the rear surface of the wafer.

3. The lift pin according to claim 2, wherein the curved surface has a radius of curvature of 8 to 15 mm.

4. The lift pin according to claim 1, wherein respective convex parts of the concavo-convex structure have a height of 0.5 to 1.5 μm.

5. The lift pin according to claim 1, wherein, among respective convex parts of the concavo-convex structure, a density of the convex parts in a central region of the head is greater than a density of the convex parts in an edge region of the head.

6. The lift pin according to claim 1, wherein, among respective convex parts of the concavo-convex structure, a height of the convex parts in a central region of the head is greater than a height of the convex parts in an edge region of the head.

7. The lift pin according to claim 1, wherein the body and the head are formed of glassy carbon.

8. The lift pin according to claim 1, wherein:
the upper surface of the head comprises a first layer formed to have a flat surface, and a second layer selectively disposed on the first layer; and
the first layer is exposed between regions of the second layer, exposed parts of the first layer form concave parts, and the second layer forms convex parts.

9. The lift pin according to claim 8, wherein at least one of shapes of the exposed parts of the first layer or a shape of the second layer configured to form the convex parts is irregular.

10. A wafer processing apparatus comprising:
a disc-shaped susceptor provided with at least three through holes formed therethrough, and configured such that a wafer is placed thereon;
at least three lift pins includes a body inserted into a through hole formed in a susceptor and a head provided at one end of the body to come into contract with a rear surface of a wafer, wherein an upper surface of the head is formed to have a concavo-convex structure, and wherein the at least three lift pins are raised and lowered in a vertical direction to support the rear surface of the wafer, and provided to correspond to the through holes, respectively; and
an elevation member configured to raise and lower the lift pins.

11. A method for producing a wafer, the method comprising:
(a) disposing a wafer processing apparatus comprising a disc-shaped susceptor provided with at least three through holes formed therethrough and configured such that the wafer is placed thereon, at least three lift pins, each lift pin comprising a body inserted into a corresponding one of the through holes in the susceptor and a head provided at one end of the body so as to come into contact with a rear surface of the wafer, raised and lowered in a vertical direction to support the rear surface of the wafer, and provided to correspond to the through holes, respectively, and an elevation member configured to raise and lower the lift pins, in a chamber;
(b) disposing the wafer on surfaces of the lift pins, and raising the lift pins by the elevation member;
(c) depositing an epitaxial layer on a surface of the wafer; and
(d) removing a silicon layer deposited on the heads of the lift pins by supplying hydrogen gas to an upper region inside the chamber and supplying hydrogen gas and hydrogen chloride to a lower region inside the chamber.

12. The method according to claim 11, wherein hydrogen gas is supplied to the upper region and the lower region inside the chamber in operation (c).

13. The method according to claim 11, wherein the same amount of hydrogen gas is supplied to the upper region and the lower region inside the chamber in operation (d).
